(19) United States
(12) Patent Application Publication
(10) Pub. No.: US 2004/0179408 A1
(43) Pub. Date: Sep. 16, 2004

(54) Microcomputer

(75) Inventor: Koichi Tanigawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/718,521

(22) Filed: Nov. 24, 2003

(30) Foreign Application Priority Data
Mar. 10, 2003 (JP) 2003-063199

(51) Int. Cl. G11C 7/00

(52) U.S. Cl. 365/191

(57) ABSTRACT

The microcomputer includes a shift resistor (20) setting a potential to bus wirings (11 to 16) in a stop mode, and the shift resistor (20) can retain a setting data by inputting serially a signal for the setting data from an external data input part (60) in synchronization with external clock from an external clock input part (70). The setting data in the shift resistor (20) is supplied to the bus wirings (11 to 16) through buffers (51 to 56) in active state. The buffers (51 to 56) are in the active state when the mode signal indicates “L” (indicating a stop mode).

### BACKGROUND OF THE INVENTION

1. Field of the Invention

The present invention relates to a microcomputer, and more particularly, it relates to a technique to detect a defect of a bus wiring such as an address bus, a data bus and so on, a word line such as a built-in ROM and so on, a bit line and so on.

2. Description of the Background Art

Conventionally, a technique disclosed in Japanese Patent Application Laid-Open No. 10-38978 (1998) is known as a technique which enables a detection of a leakage defect easily, in a matter of minutes and with a high degree of accuracy with setting signal levels of all word lines simultaneously by selecting a test signal supplying a certain word line pattern and outputting the test signal to a memory such as a ROM and so on in a special operating mode (a stop mode) stopping an oscillation of a clock in the microcomputer.

However, with regard to such a conventional technique, the test signal supplying the predetermined word line pattern is employed in the stop mode, thus a supply source of the test signal needs to be provided separately and a cost increases.

### SUMMARY OF THE INVENTION

It is an object to provide a low-cost microcomputer which can detect a defect in a plurality of signal lines such as word lines transmitting a signal of a CPU and so on.

According to a first aspect of the present invention, a microcomputer includes a CPU, a plurality of signal lines, a data memory part, a first and a second signal transmitting means and a signal transmitting control means.

The plurality of signal lines are provided corresponding to an output signal of the CPU. The data memory part is capable of storing a setting data corresponding to the plurality of signal lines on the basis of an external signal. The first signal transmitting means transmits the output signal of the CPU to the plurality of signal lines in an active state. The second signal transmitting means transmits the setting data of the data memory part to the plurality of signal lines in an active state.

The signal transmitting control means controls an activity/an inactivity of the first and the second signal transmitting means. Moreover, the signal transmitting control means receives a mode signal, and forces only the first signal transmitting means to be in an active state when the mode signal indicates a normal state, and forces only the second signal transmitting means to be in an active state when the mode signal indicates a special state.

The invention of the first aspect enables a potential setting by the setting data stored in the data memory part in the special state to the plurality of signal lines, thus a test potential setting to the plurality of signal lines can be performed without having a test signal supply source separately. As a result, the low-cost microcomputer which can detect the defect in the plurality of signal lines transmitting the signal of the CPU can be obtained.

According to a second aspect of the present invention, a microcomputer includes a CPU, a memory part, a main decoder and a sub-decode part.

The CPU outputs a multibit address signal for selection of a word line. The memory part has a plurality of word lines. The main decoder performs a decode processing on the basis of a main address signal except for a least significant bit address signal in the address signal to obtain a main decode result.

The sub-decode part receives the main decode result, the least significant bit address signal and a mode signal, and performs a potential setting of the plurality of word lines. At this time, when the mode signal indicates a normal state, the sub-decode part sets one of the plurality of word lines to a potential in a selective state on the basis of the main decode result and the least significant bit address signal, and when the mode signal indicates a special state, the sub-decode part performs a potential setting of the plurality of word lines only on the basis of the least significant bit address signal.

The invention of the second aspect can perform the potential setting of “H” and “L” by turns to the plurality of word lines placed normally in order of address by performing the potential setting of the plurality of word lines only on the basis of the least significant bit address signal in the special state, and as a result, enables a detection of a defect such as a short of the word line and so on with a high degree of accuracy by measuring a power source current in this state.

Moreover, the invention of the second aspect can perform a normal word line selecting action setting one of the plurality of word lines to the potential in the selective state on the basis of the main decode result and the least significant bit address signal by the main decoder and the sub-decode part in the normal state, thus with regard to a word line selecting means, it is possible to reduce an additional circuit and control a production cost.

According to a third aspect of the present invention, a microcomputer includes a CPU, a memory part, a word line selecting means and a bit line potential setting part.

The CPU outputs a multibit address signal. The memory part has a plurality of word lines and a plurality of bit lines. The word line selecting means receives a mode signal, selects one of the plurality of word lines on the basis of the address signal when the mode signal indicates a normal state, and forces all of the plurality of word lines to be in non-selective state when the mode signal indicates a special state. The bit line potential setting part receives the mode signal, is in an active state when the mode signal indicates a special state and performs a potential setting of the plurality of bit lines in a predetermined mode.

In the invention of the third aspect, all of the plurality of word lines are made to be in non-selective state by the word line selecting means in the special state, the potential setting of the plurality of bit lines is performed in the predetermined mode by the bit line potential setting part. Accordingly, it is possible to detect a defect such as a short of the bit line and so on with a high degree of accuracy by setting the predetermined mode so that the potential setting of “H” and “L” by turns is performed to the plurality of bit lines and measuring a power source current in this state, for example.

Furthermore, the word line selecting means can perform a normal word line selecting action selecting one of the plurality of word lines on the basis of the address signal in the normal state, thus with regard to the word line selecting means, it is possible to reduce an additional circuit and control a production cost.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating a composition of a main part in a microcomputer that is a preferred embodiment 1 of the present invention.

FIG. 2 is a circuit diagram illustrating a composition of a main part in a microcomputer that is a preferred embodiment 2 of the present invention.

FIG. 3 is a circuit diagram illustrating a composition of a main part in a microcomputer that is a preferred embodiment 3 of the present invention.

FIG. 4 is a circuit diagram illustrating a composition of a main part in a microcomputer that is a preferred embodiment 4 of the present invention.

FIG. 5 is a block diagram illustrating a composition of a main part of a microcomputer that is a preferred embodiment 5 of the present invention.

FIG. 6 is a circuit diagram illustrating a composition of a word line address decode circuit in FIG. 5.

FIG. 7 is a circuit diagram illustrating a composition of a main part in a microcomputer that is a preferred embodiment 6 of the present invention.

### DESCRIPTION OF THE PREFERRED EMBODIMENTS

### Preferred Embodiment 1

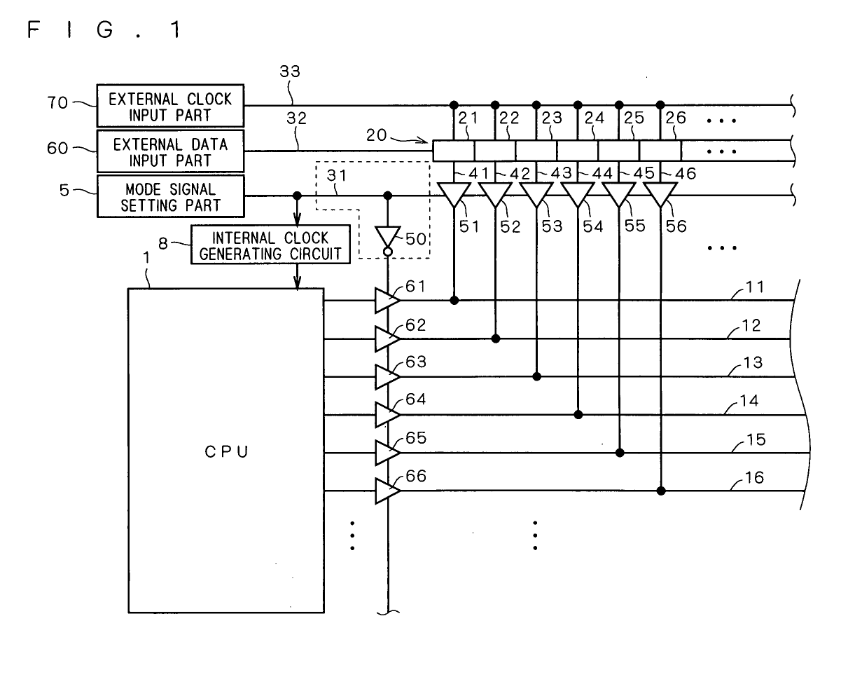

FIG. 1 is a circuit diagram illustrating a composition of a main part in a microcomputer that is the preferred embodiment 1 of the present invention. The microcomputer according to the present preferred embodiment includes a CPU 1 which has a control means, and peripheral apparatuses such as a program counter (illustration omitted), a decoder (illustration omitted), a ROM (illustration omitted) and others, and the CPU 1 and the peripheral apparatuses such as the ROM and so on interact with each other by bus wirings 11, 12, 13, 14, 15, 16, . . . (abbreviate to “bus wirings 11 to 16” hereinafter) such as an address bus, a data bus and so on placed in parallel. These bus wirings 11 to 16 correspond to a plurality of signal lines provided corresponding with an output signal of a CPU.

Moreover, this microcomputer has a normal mode to perform a normal operational process on the basis of a clock oscillation and a stop mode to stop the clock oscillation, make the CPU 1 stop and reduce a consumed current. These mode indications are determined by a mode signal supplied by a mode signal setting part 5.

The microcomputer has an internal clock generating circuit 8 inside, and the internal clock generating circuit 8 receives the mode signal from the mode signal setting part 5 and stops a generation (an oscillation) of an internal clock, when the mode signal indicates the stop mode.

The output signal of this CPU 1 is supplied to buffers 61, 62, 63, 64, 65, 66, . . . (abbreviated to “buffers 61 to 66” hereinafter), and the buffers 61 to 66 amplifies the output signal described above and supplies it to the bus wirings 11 to 16 in an active state.

The microcomputer includes a shift resistor 20 setting a potential in the stop mode (corresponding to a data memory part) to the bus wirings 11 to 16, and the shift resistor 20 is composed of one bit latch parts 21, 22, 23, 24, 25, 26, . . . (abbreviated to “one bit latch parts 21 to 26” hereinafter). The one bit latch parts 21 to 26 are composed of a flip-flop, respectively, and take in an input signal of a previous stage in synchronization with a clock inputted to a clock input. A data stored in this shift resistor 20 becomes a setting data to the bus wirings 11 to 16 in the stop mode.

The one bit latch parts 21 to 26 are connected with the bus wirings 11 to 16 through wirings 41, 42, 43, 44, 45, 46, . . . (abbreviated to “wirings 41 to 46” hereinafter) and buffers 51, 52, 53, 54, 55, 56, . . . (abbreviated to “buffers 51 to 56” hereinafter).

The buffers 51 to 56 (corresponding to a second signal transmitting means) amplify the data stored in the one bit latch parts 21 to 26 and supply it to the bus wirings 11 to 16 in the active state.

Moreover, an operator can set a potential pattern which is supposed to be set to the respective bus wirings 11 to 16 in the stop mode (corresponding to the setting data) to the shift resistor 20 as described above, and the microcomputer includes an external data input part 60 to input the potential pattern and an external clock input part 70 inputting an external clock to control a data input of the shift resistor 20 in the stop mode. Moreover, the mode signal setting part 5 is provided for a mode signal input indicating either the normal mode or the stop mode.

The mode signal setting part 5 is connected with an internal signal line 31, and the signal line 31 is connected with not only respective control inputs of the buffers 51 to 56 electrically but also an input part of an inverter 50. An output of the inverter 50 is supplied to respective control inputs of the buffers 61 to 66.

A signal transmitting control means composed of the signal line 31 and the inverter 50 forces the buffers 61 to 66 to be in the active state selectively when the mode signal indicates “L” (indicating the normal mode), and forces the buffers 51 to 56 to be in the active state selectively when the mode signal indicates “H” (indicating the stop mode) in the buffers 51 to 56 and 61 to 66.

When the control input indicates “H”, the buffers 51 to 56 and the buffers 61 to 66 are in the active state and output a signal to the bus wirings 11 to 16, respectively, and when the control input indicates “L”, they are supposed to be in the inactive state, are supposed to be in a floating state, and do not output the signal to the bus wirings 11 to 16.

The external data input part 60 is connected with an input of the one bit latch part 21 that is a first stage of the shift resistor 20 through a signal line 32. The external clock input part 70 is supplied to a clock input part of the one bit latch parts 21 to 26 through the signal line 33.

In such a constitution, when the mode signal indicating the normal mode of “L” is set to the mode signal setting part 5 in the microcomputer, the buffers 61 to 66 are in the active state, and the buffers 51 to 56 are in the inactive state as described above. Accordingly, the date in the shift resistor 20 is not supplied to the bus wirings 11 to 16, but the output signal from the CPU 1 is supplied to the bus wirings 11 to 16 through the buffers 61 to 66. That is to say, the potential setting of the bus wirings 11 to 16 by the normal CPU 1 is performed.

In the meantime, when the mode signal indicating the stop mode of “H” is set to the mode signal setting part 5, an internal clock generating circuit 8 stops a generation of an internal clock, and the buffers 61 to 66 are in the inactive state, and the buffers 51 to 56 are in the active state. Accordingly, the data in the shift resistor 20 is supplied to the bus wirings 11 to 16, and the output signal from the CPU 1 is not supplied to the bus wirings 11 to 16.

That is to say, the setting data retained in the respective one bit latch parts 21 to 26 of the shift resistor 20 is supplied to the bus wirings 11 to 16 through the wirings 41 to 46 and the buffers 51 to 56. This setting data is a data that the operator makes the shift resistor 20 retain a requested data through the external data input part 60 in the stop mode.

Concretely, the setting data is retained in the respective one bit latch parts 21 to 26 by supplying a signal for the setting data serially and sequentially from the external data input part 60 with supplying the external clock from the external clock input part 70 to the respective clock inputs of the one bit latch parts 21 to 26 of the shift resistor 20. In this manner, with regard to this microcomputer, the setting data to the respective bus wirings 11 to 16 can be changed when the operator changes a designation of the setting data to the external data input part 60 in the stop mode.

In the meantime, with regard to the conventional microcomputer, when the oscillation is entirely made to stop, an address line such as the bus wiring like the address bus, the data bus and so on, the ROM and so on retains a state right before entering the stop mode. Accordingly, for example, in case that there is such a defect on a certain specific address bus as a current flows only in a state that the certain specific address bus is in the “H” level, there is a possibility that the defect can not be detected according to a test data employed at a shipment test. Moreover, there is also a case that a leakage defect that a current flows between the bus wirings adjacent to each other by an insulation failure between those wirings cannot be detected according to the test data. Furthermore, there is a problem that a testing time increases even if the tests can be performed with a various combination with employing a plurality of test patterns.

On the contrary, with regard to the microcomputer of the present preferred embodiment, the setting data can arbitrary be designated through the external data input part 60 in the stop mode, thus a test employing the plurality of test patterns can rapidly be performed by measuring a value of a power source current (a current flowing from a power source to a ground) and so on with changing variously the setting data of the bus wiring. Particularly, a leakage test can easily be performed by measuring the value of the power source current with setting the setting data that the potentials are different between the bus wirings adjacent to each other.

Furthermore, by retaining the signal of the setting data in the shift resistor 20, the data setting of it to the bus wirings 11 to 16 is attained, thus a circuit composition for the setting of the setting data to the shift resistor 20 can become easy.

### Preferred Embodiment 2

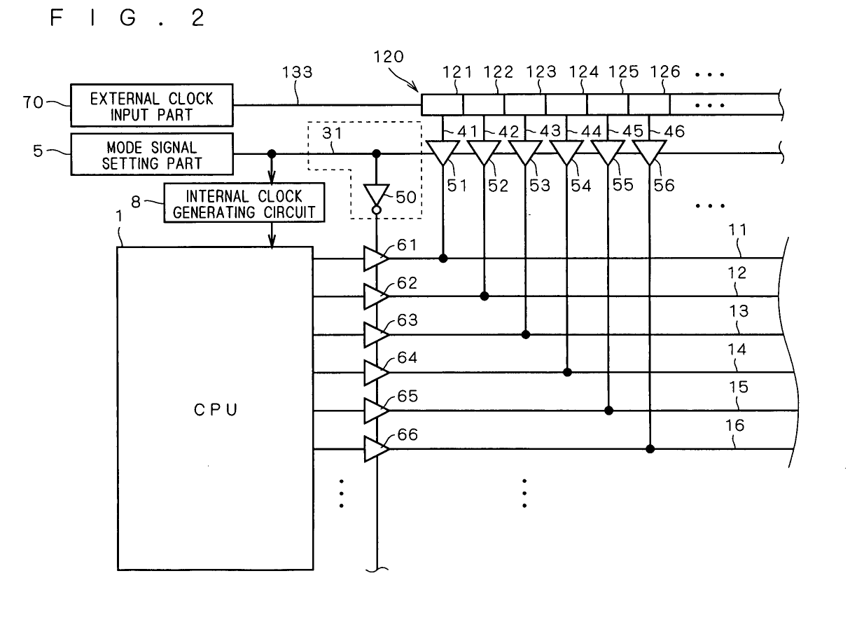

FIG. 2 is a circuit diagram illustrating a composition of a main part in a microcomputer that is the preferred embodiment 2 of the present invention.

With regard to the preferred embodiment 2, in case of comparing with the composition of the preferred embodiment 1 shown in FIG. 1, the composition is different in that an increment counter 120 is provided in exchange for the shift resistor 20, the external data input part 60 is omitted and the external clock input part 70 is supplied to a count input part of the increment counter 120 through the signal line 33. Moreover, one bit count parts 121, 122, 123, 124, 125, 126, . . . (abbreviated to “one bit count parts 121 to 126” hereinafter) are connected with the buffers 51 to 56 through the wirings 41 to 46. Besides, the one bit count parts 121 to 126 are composed of a flip-flop and so on, respectively. Besides, other composition is similar to the composition of the preferred embodiment 1 shown in FIG. 1, thus the description is omitted.

When the increment counter 120 detects a predetermined signal transition change (a building-up edge and a falling edge) of the external clock inputted form the external clock input part 70, it performs a count action of an increment “1”.

In such a composition, when the mode signal indicating the normal mode of “L” is set to the mode signal setting part 5 in the microcomputer, the buffers 61 to 66 are in the active state, and the buffers 51 to 56 are in the inactive state. Accordingly, the date in the increment counter 120 is not supplied to the bus wirings 11 to 16, but the output signal from the CPU 1 is supplied to the bus wirings 11 to 16 through the buffers 61 to 66.

In the meantime, when the mode signal indicating the stop mode of “H” is set to the mode signal setting part 5, the internal clock generating circuit 8 stops the generation of the internal clock, and the buffers 61 to 66 are in the inactive state, and the buffers 51 to 56 are in the active state. Accordingly, the setting data in the increment counter 120 is supplied to the bus wirings 11 to 16, and the output signal from the CPU 1 is not supplied to the bus wirings 11 to 16.

That is to say, the setting data retained in the respective one bit count parts 121 to 126 of the increment counter 120 is supplied to the bus wirings 11 to 16 through the wirings 41 to 46 and the buffers 51 to 56. This setting data is a data that the operator makes the increment counter 120 retain a requested data through the external clock input part 70 in the stop mode.

Concretely, a count value is retained as the setting data in the respective one bit count parts 121 to 126 of the increment counter 120 by supplying an external clock of clock numbers corresponding to the requested data from the external clock input part 70 to the count input part of the increment counter 120. In this manner, with regard to the microcomputer of the preferred embodiment 2, the setting data to the respective bus wirings 11 to 16 can be changed when the operator changes contents of the setting data through the external clock input part 70 in the stop mode.

With regard to the microcomputer of the present preferred embodiment, the setting data can arbitrary be designated through the external clock input part 70 in the stop mode, thus a test employing the plurality of test patterns can rapidly be performed by measuring a value of a power source current and so on with changing variously the setting data of the bus wiring.

Furthermore, by retaining the signal of the setting data in the increment counter 120, the data setting of it to the bus wirings 11 to 16 is attained, thus a circuit composition for the setting of the setting data to the increment counter 120 can become easy.

### Preferred Embodiment 3

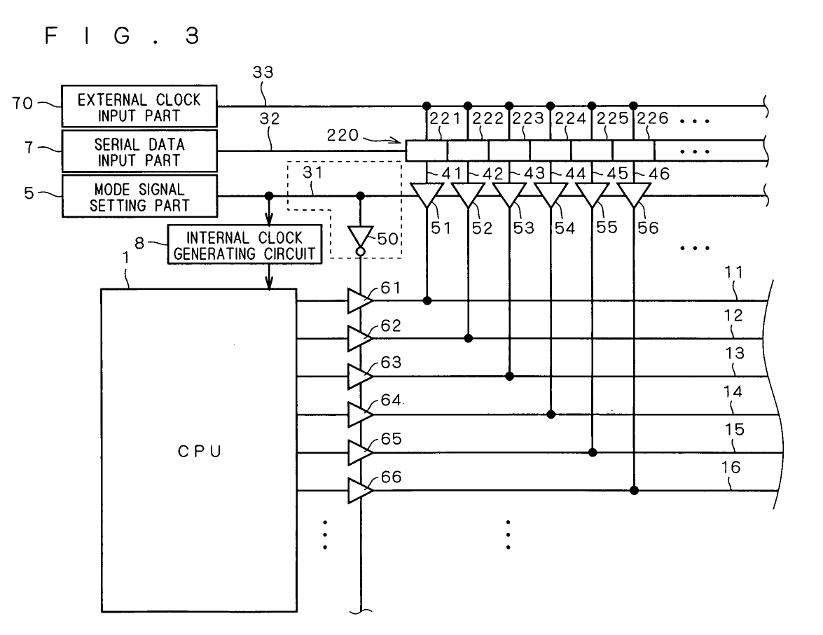

FIG. 3 is a circuit diagram illustrating a composition of a main part in a microcomputer that is preferred embodiment 3 of the present invention. As shown in FIG. 3, it is different in that a built-in serial I/O 220 which is originally built in the microcomputer is employed in exchange for the shift resistor 20 and according to this, a serial data input part 7 which is provided corresponding to the built-in serial I/O 220 is also employed as an external data input part in a stop mode. Accordingly, the exclusive external data input part 60 as described in the preferred embodiment 1 becomes unnecessary.

The built-in serial I/O 220 is composed of one bit latch parts 221, 222, 223, 224, 225, 226, . . . (abbreviated to “one bit latch parts 221 to 226” hereinafter), inputs an external serial data received from the serial data input part 7 in synchronization with the external clock received from the external clock input part 70 and transfers it serially from the one bit latch part 221 to the one bit latch part 226.

The one bit latch parts 221 to 226 are connected with the bus wirings 11 to 16 through the wirings 41 to 46 and the buffers 51 to 56. Other composition is similar to the composition of the preferred embodiment 1, thus the description is omitted.

In such a composition, when the mode signal indicating the normal mode of “L” is set to the mode signal setting part 5, the buffers 61 to 66 are supposed to be in the active state, and the buffers 51 to 56 are supposed to be in the inactive state. Accordingly, the date in the built-in serial I/O 220 is not supplied to the bus wirings 11 to 16, but the output signal from the CPU 1 is supplied to the bus wirings 11 to 16 through the buffers 61 to 66.

In the meantime, when the mode signal indicating the stop mode of “H” is set to the mode signal setting part 5, the internal clock generating circuit 8 stops the generation of the internal clock, and the buffers 61 to 66 are supposed to be in the inactive state, and the buffers 51 to 56 are supposed to be in the active state. Accordingly, the setting data in the built-in serial I/O 220 is supplied to the bus wirings 11 to 16, and the output signal from the CPU 1 is not supplied to the bus wirings 11 to 16.

That is to say, the setting data retained in the respective one bit latch parts 221 to 226 of the built-in serial I/O 220 is supplied to the bus wirings 11 to 16 through the wirings 41 to 46 and the buffers 51 to 56. This setting data is a data that the operator makes the built-in serial I/O 220 retain a requested data through the serial data input part 7 in the stop mode. The data setting to the built-in serial I/O 220 is performed in the same manner as the data setting to the shift resistor 20 of the preferred embodiment 1.

Accordingly, with regard to the microcomputer of the present preferred embodiment, the setting data can arbitrary be designated through the serial data input part 7 in the stop mode, thus a test employing the plurality of test patterns can rapidly be performed by measuring a value of a power source current and so on with changing variously the setting data of the bus wiring. Particularly, a leakage test can easily be performed by measuring the value of the power source current with setting the setting data that the potentials are different between the bus wirings adjacent to each other.

Furthermore, for example, in case that an initial value of the built-in serial I/O 220 is indicated as “10101010” in a binary number, a value of a serial interface comes to be indicated as “01010101” only when “0” is inputted to the signal line 33 for one clock after making a transition to the stop mode, and different values can be set easily and rapidly to all of the bus wirings. Moreover, the setting data is set to the respective bus wirings 11 to 16 employing the built-in serial I/O 220 which is built in, thus an effect described above can be obtained with controlling newly added components to be little (with omitting the shift resistor 20, the external data input part 60 and so on of the preferred embodiment 1).

### Preferred Embodiment 4

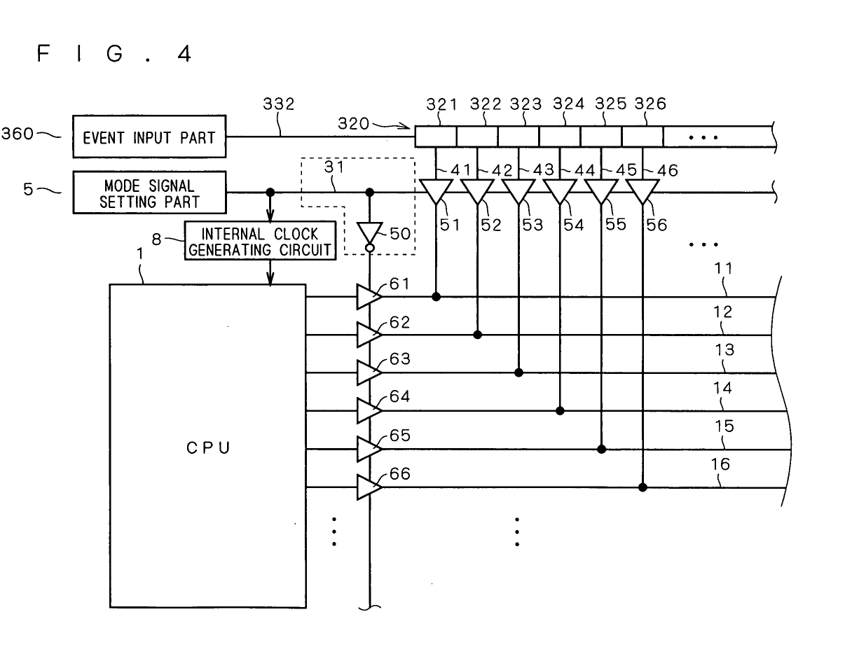

FIG. 4 is a circuit diagram illustrating a composition of a main part in a microcomputer that is the preferred embodiment 4 of the present invention.

With regard to the preferred embodiment 4, in case of comparing with the composition of the preferred embodiment 2 shown in FIG. 2, the composition is different in that a built-in timer 320 is provided in exchange for the increment counter 120 and an event input part 360 is provided in exchange for the external clock input part 70.

A count value having multibit structure by count bit parts 321, 322, 323, 324, 325, 326, . . . (abbreviated to “count bit parts 321 to 326” hereinafter) of the built-in timer 320 can be set as a chrometry value. That is to say, the built-in timer 320 performs an up-count or a down-count of the count value on the basis of a predetermined signal transition change (a building-up edge and a falling edge) caused at a predetermined time interval in an event signal inputted from the event input part 360.

The count bit parts 321 to 326 of the built-in timer 320 is connected with the buffers 51 to 56 through the wirings 41 to 46. Besides, other composition is similar to the composition of the preferred embodiment 2 shown in FIG. 2, thus the description is omitted.

In such a composition, when the mode signal indicating the normal mode of “L” is set to the mode signal setting part 5, the buffers 61 to 66 are supposed to be in the active state, and the buffers 51 to 56 are supposed to be in the inactive state. Accordingly, the setting date in the built-in timer 320 (the count value) is not supplied to the bus wirings 11 to 16, but the output signal from the CPU 1 is supplied to the bus wirings 11 to 16 through the buffers 61 to 66.

In the meantime, when the mode signal indicating the stop mode of “H” is set to the mode signal setting part 5, the internal clock generating circuit 8 stops the generation of the internal clock, and the buffers 61 to 66 are supposed to be in the inactive state, and the buffers 51 to 56 are supposed to be in the active state. Accordingly, the setting data in the built-in timer 320 (the count value) is supplied to the bus wirings 11 to 16, and the output signal from the CPU 1 is not supplied to the bus wirings 11 to 16.

That is to say, the setting data retained in the respective count bit parts 321 to 326 of the built-in timer 320 is supplied to the bus wirings 11 to 16 through the wirings 41 to 46 and the buffers 51 to 56. This setting data is a data that the operator makes the built-in timer 320 retain a requested data through the external clock input part 70 in the stop mode.

Concretely, the setting data is retained in the respective count bit parts 321 to 326 of the built-in timer 320 by supplying an edge change of the event signal corresponding to the requested data from the event input part 360 to the count input part of the built-in timer 320. In this manner, with regard to this microcomputer, the setting data to the respective bus wirings 11 to 16 can be changed when the operator changes contents of the setting data through the event input part 360 in the stop mode.

With regard to the microcomputer of the present preferred embodiment, the setting data can arbitrary be designated through the event input part 360 in the stop mode, thus a test employing the plurality of test patterns can rapidly be performed by measuring a value of a power source current and so on with changing variously the setting data of the bus wiring.

Furthermore, the setting data is set to the respective bus wirings 11 to 16 employing the built-in timer 320 which is built-in, thus an effect described above can be obtained with controlling the newly added components to be little (with omitting the external clock input part 70, the increment counter 120 and so on of the preferred embodiment 2).

### Preferred Embodiment 5

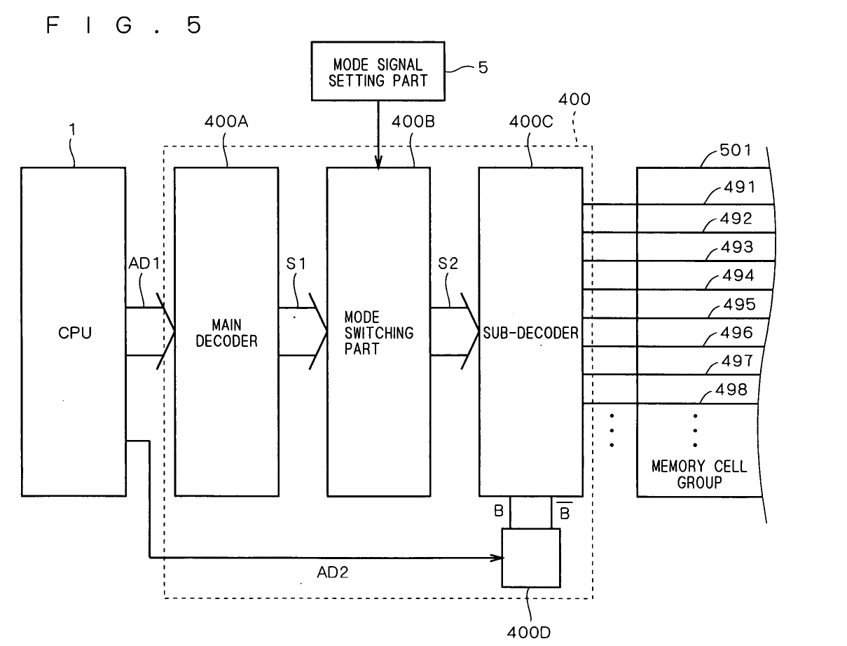

FIG. 5 is a block diagram illustrating a composition of a main part of a microcomputer that is the preferred embodiment 5 of the present invention.

As shown in FIG. 5, a main address signal ADI that a last (bit) address is eliminated from an address signal to select a word line outputted from the CPU 1 is outputted to a main decoder 400A, and a last address signal AD2 is outputted to a last address processing part 400D.

The main decoder 400A perform a decode process on the basis of the main address signal AD 1 and outputs a main decode result S1.

When a mode signal indicates a normal mode, a mode switching part 400B outputs the main decode result S1 as a select decode result S2 without change, and when the mode signal indicates a stop mode, it outputs a fixed data (all “0” (“L”)) as the select decode result S2, on the basis of a mode signal obtained from the mode signal setting part 5.

In the meantime, the last address processing part 400D sets either a last address bit signal B or an inversion last address bit signal B to be “H” and the other to be “L”, on the basis of the last address signal AD2.

A sub-decoder 400C performs a potential setting of word lines 491, 492, . . . , 498, . . . (abbreviated to “word lines 491 to 498” hereinafter) of a memory cell group 501, on the basis of the select decode result S2, the last address bit signal B and the inversion last address bit signal \overline{B}.

A word line address decode circuit 400 is composed of the main decoder 400A, the mode switching part 400B, the sub-decoder 400C and the last address processing part 400D described above, and a sub-decode part is composed of the mode switching part 400B, the sub-decoder 400C and the last address processing part 400D.

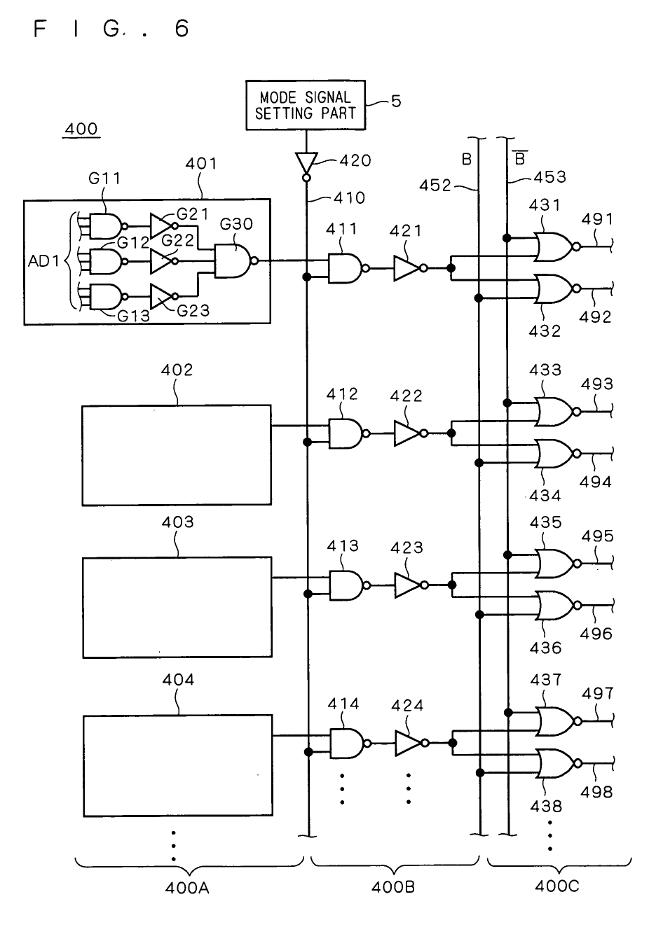

FIG. 6 is a circuit diagram illustrating a composition of a main part of the word line address decode circuit 400 shown in FIG. 5. Besides, an illustration of the last address processing part 400D is omitted in FIG. 6.

An input edge of the word line address decode circuit 400 is connected with a program counter of the CPU 1 and so on which are not shown in FIG. 6 by the address bus, and moreover, an output edge of it is connected with the memory cell group 501 which is a memory part of the ROM and so on by the word lines 491 to 498.

Moreover, the main decoder 400A includes decoders 401, 402, 403, 404, . . . (abbreviated to “decoders 401 to 404” hereinafter) which decode the main address signal AD1 except for the least significant bit of the address selecting the word line, respectively.

The decoder 401 has NAND gates G11 to G13 in a first stage, inverters G21 to G23 in a second stage and a NAND gate G30 in a third stage, and when the main address signal AD1 which is previously corresponded to it (the address signal except for the least significant bit) is inputted, it outputs “H”, and outputs “L” in the other case. Besides, particulars are not illustrated in the decoders 402 to 404 in FIG. 6, but the circuits similar to the circuit shown in the decoder 401 are provided. Accordingly, only the output from one of the decoders 401 to 404 is supposed to be “L” on the basis of the main address signal AD1.

The mode switching part 400B includes NAND gates 411, 412, 413, 414, . . . (abbreviated to “NAND gates 411 to 414” hereinafter), inverters 421, 422, 423, 424, . . . (abbreviated to “inverters 421 to 424” hereinafter), NOR gates 431, 432, . . . , 438, . . . (abbreviated to “NOR gates 431 to 438” hereinafter), a signal line 410 and an inverter 420.

Concretely, a mode signal supplied from the mode signal setting part 5 is supplied to the signal line 410 through the inverter 420. Moreover, outputs from the decoders 401 to 404 are connected with inputs of one part of the NAND gates 411 to 414, and the signal line 410 is connected with the inputs of the other part of the NAND gates 411 to 414 in common. An output from the NAND gates 411 to 414 is supplied to an input of the respective inverters 421 to 424.

In the sub-decoder 400C, inputs of one part of the NOR gates 431, 433, 435 and 437 are connected with a signal line 453 in common, and outputs from the inverters 421 to 424 is connected with inputs of the other part. Inputs of one part of the NOR gates 432, 434, 436 and 438 are connected with a signal line 452 in common, and outputs from the inverters 421 to 424 is connected with inputs of the other part.

Moreover, the last address bit signal B is supplied to a signal line 452 of the sub-decoder 400C, and the inversion last address bit signal B is supplied to the signal line 453.

With regard to such a composition, when the mode signal of “L” indicating the normal mode is supplied to the mode signal setting part 5, the signal line 410 becomes “H”, thus the output from the main decoder 400A (the main decode result S1 in FIG. 5) becomes effective and is supplied to the inputs of the one part of the NOR gates 431 to 438. As a result, a normal word line selecting action that one of the word lines 491 to 498 is selected by an output signal of “L” (selective state) in the decoders 401 to 404 and “H”/“L” of the last address bit signal B and of the inversion last address bit signal \overline{B} is performed.

In the meantime, when the mode signal of “H” indicating the stop mode is supplied to the mode signal setting part 5, the signal line 410 becomes “L”, thus the output from the main decoder 400A ceases to be in effect, and the inputs of the one part of the NOR gates 431 to 438 are entirely fixed to be “L” (the select decode result S2 in FIG. 5 becomes all “0”). As a result, the word lines 491 to 498 adjacent to each other are necessarily set to be “H”, “L”, “H” and “L” by turns by the last address bit signal B and the inversion last address bit signal \overline{B} supplied to the signal lines 452 and 453.

The composition is such as the description described above, according to the microcomputer according to the preferred embodiment 5, different potentials are set to the every other word line in the stop mode, and by measuring a power source current in this state, it is possible to detect a defect (a leakage defect) such as a short of the word line and so on with a high degree of accuracy.

Moreover, a signal identical with that in a normal action, that is to say, the address signal selecting the word line is employed as it is as a signal source to set a value to the word line. Accordingly, the word line address decode circuit can be employed in the normal mode and the stop mode in common, thus it is possible to reduce an additional circuit and control a production cost.

### Preferred Embodiment 6

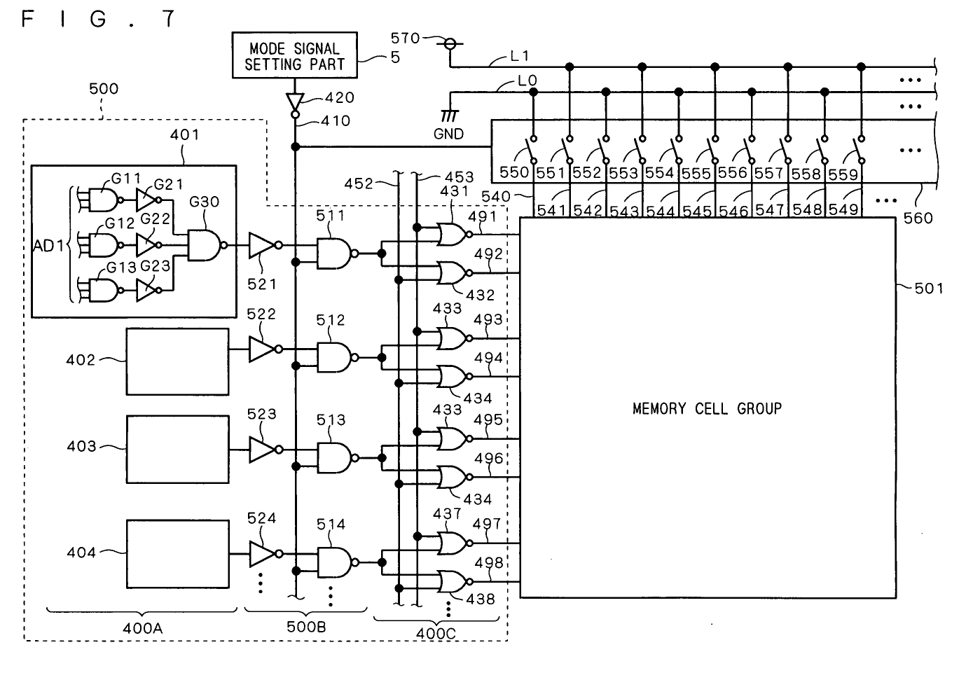

FIG. 7 is a circuit diagram illustrating a composition of a main part in a microcomputer that is the preferred embodiment 6 of the present invention.

In FIG. 7, a plurality of memory cells in the memory cell group 501 of the memory part such as the ROM and so on (not shown in FIG. 7) is placed in a matrix pattern, connected with the word lines 491 to 498 in line-at-a time and connected with bit lines 540, 541, . . . , 539, . . . , (abbreviated with “bit line 540 to 549” hereinafter) in row unit.

The word lines 491 to 498 are decoded by a word line address decode circuit 500 which is a word line selecting circuit. In the same manner as the word line address decode circuit 400 in the preferred embodiment 5, the word line address decode circuit 500 has not only the main decoder 400A, the sub-decoder 400C and the last address processing part 400D (not shown in FIG. 7) but also a mode switching part 500B in exchange for the mode switching part 400B.

The mode switching part 500B is composed of inverters 521, 522, 523, 524, . . . , (abbreviated to “inverters 521 to 524” hereinafter), NAND gates 511, 512, 513, 514, . . . , (abbreviated with “NAND gates 511 to 514” hereinafter), the signal line 410 and the inverter 420.

The mode signal supplied by the mode signal setting part 5 is supplied to the signal line 410 through the inverter 420. The inverters 521 to 524 receives an output of the decoder 401 to 404, and the NAND gates 511 to 514 receives an output of the inverters 521 to 524 in inputs of one part, and inputs of the other part are connected with the signal line 410 in common. Besides, other composition of the word line address decode circuit 500 is similar to the word line address decode circuit 400 of the preferred embodiment 5, thus the description is omitted.

In the meantime, the bit lines 540 to 549 are connected with not only an input/output buffer to read-out and write-in which is not shown in FIG. 7 and so on but also a switch circuit group 560 corresponding to a bit line potential setting part.

The switch circuit group 560 has switch circuits 550, 551, . . . , 559, . . . (abbreviated to “switch circuits 550 to 559” hereinafter) connected electrically with the bit lines 540 to 549, and these switch circuits 550 to 559 are in on-state in common when the mode signal supplied from the mode signal setting part 5 indicates “H”, and are in off-state in common when the mode signal supplied from the mode signal setting part 5 indicates “L”.

The switch circuits 550, 552, 554, 556 and 558 are connected electrically with a ground wiring L0 in on-state, and the switch circuits 551, 553, 555, 557 and 559 are connected electrically with a power source wiring L1 in off-state.

With regard to such a composition, when the mode signal of “L” is supplied to the mode signal setting part 5 in the normal mode, one of the outputs of the decoders 401 to 404 becomes “L”, thus one of the outputs of the NAND gates 511 to 514 becomes “L”, and as a result, one of the word lines 491 to 498 is selected, and a normal word line selecting action accompanying a normal read-out/write-in action is performed to the memory cell group 501. At this time, the switch circuits 550 to 559 of the switch circuit group 560 are entirely in off-state.

In the meantime, the mode signal of “H” is supplied to the mode signal setting part 5 in the stop mode, the decode result of the main decoder 400A is voided, and the NAND gates 511 to 514 becomes “H” by compulsion. As a result, the last address bit signal B and the inversion last address bit signal B are also voided, and all of the word lines 591 to 598 are supposed to be in non-selective state by being fixed to be “L” by compulsion.

Moreover, all of the switch circuits 550 to 559 in the switch circuit group 560 are supposed to be in on-state, and the bit lines 540 to 549 adjacent to each other are set to be “H” and “L” by turns.

The composition is such as the description described above, according to the microcomputer according to the preferred embodiment 6, different potentials are set to the every other bit lines 540 to 549 adjacent to each other in the stop mode, and by measuring a power source current in this state, it is possible to detect a defect (a leakage defect) such as a short of the bit lines 540 to 549 and so on with a high degree of accuracy.

Moreover, a signal identical with that in the normal action, that is to say, the address signal selecting the word line is employed as a signal source to set the value to the word line, thus with regard to the word line address decode circuit 500, in the same manner as the preferred embodiment 5, it is possible to reduce an additional circuit and control a production cost.

While the invention has been shown and described in detail, the foregoing description is in all aspects illustrative and not restrictive. It is therefore understood that numerous modifications and variations can be devised without departing from the scope of the invention.

What is claimed is:

1. A microcomputer, comprising:
a CPU;
a plurality of signal lines provided corresponding to an output signal of said CPU;
a data memory part being capable of storing a setting data corresponding to said plurality of signal lines on the basis of an external signal;
a first signal transmitting means transmitting said output signal of said CPU to said plurality of signal lines in an active state;
a second signal transmitting means transmitting said setting data of said data memory part to said plurality of signal lines in an active state; and
signal transmitting control means controlling an activity/an inactivity of said first and second signal transmitting means; wherein
said signal transmitting control means receives a mode signal, and forces only said first signal transmitting means to be in an active state when said mode signal indicates a normal state, and forces only said second signal transmitting means to be in an active state when said mode signal indicates a special state.

2. The microcomputer according to claim 1, wherein
said external signal includes a serial data, and
said data memory part includes a data memory part having multibit structure and storing said setting data by taking in said external signal with shifting.

3. The microcomputer according to claim 2, wherein
said data memory part includes a data memory part employed as a serial I/O in a normal action of said microcomputer.

4. The microcomputer according to claim 1, wherein
said external signal includes a timing signal performing a predetermined signal transition change at a predetermined timing, and
said data memory part includes a data memory part having multibit structure and counting a number of said predetermined signal transition change of said timing signal as said setting data.

5. The microcomputer according to claim 4, wherein
said data memory part includes a data memory part employed as a timer in a normal action of said microcomputer.

6. A microcomputer, comprising:
a CPU outputting a multibit address signal for selection of a word line;
a memory part having a plurality of word lines;
a main decoder performing a decode processing on the basis of a main address signal except for a least significant bit address signal in said address signal to obtain a main decode result;
a sub-decode part receiving said main decode result, said least significant bit address signal and a mode signal, and performing a potential setting of said plurality of word lines; wherein
when said mode signal indicates a normal state, said sub-decode part sets one of said plurality of word lines to a potential in a selective state on the basis of said main decode result and said least significant bit address signal, and when said mode signal indicates a special state, said sub-decode part performs a potential setting of said plurality of word lines only on the basis of said least significant bit address signal.

7. A microcomputer, comprising:
a CPU outputting a multibit address signal;
a memory part having a plurality of word lines and a plurality of bit lines;
a word line selecting means receiving a mode signal, selecting one of plurality of word lines on the basis of said address signal when said mode signal indicates a normal state, and forcing all of said plurality of word lines to be in non-selective state when said mode signal indicates a special state; and
a bit line potential setting part receiving said mode signal, being in an active state when said mode signal indicates a special state and performing a potential setting of said plurality of bit lines in a predetermined mode.
